(19) United States
(12) Patent Application Publication
(10) Pub. No.: US 2013/0207151 A1
(43) Pub. Date: Aug. 15, 2013

(54) Optoelectronic Semiconductor Component And Method For Producing Same

(71) Applicants: Angela Eberhardt, Augsburg (DE); Roland Huettinger, Kaufering (DE); Stefan Kotter, Augsburg (DE); Reinhold Schmidt, Augsburg (DE)

(72) Inventors: Angela Eberhardt, Augsburg (DE); Roland Huettinger, Kaufering (DE); Stefan Kotter, Augsburg (DE); Reinhold Schmidt, Augsburg (DE)

(73) Assignee: OSRAM GMBH, Muenchen (DE)

(21) Appl. No.: 13/878,249

(22) PCT Filed: Oct. 5, 2011
(86) PCT No.: PCT/EP2011/067381

§ 371 Date: Apr. 8, 2013

(30) Foreign Application Priority Data
Oct. 8, 2010 (DE) 10 2010 042 217.7

(51) Int. Cl. H01L 33/64; H01L 33/50

(52) U.S. Cl. CPC H01L 33/641; H01L 33/50
USPC 257/98; 438/29

(57) ABSTRACT

An optoelectronic semiconductor component includes a light source, a housing and electrical connections, wherein the light source has a chip which emits primary radiation in the UV or blue region with a peak wavelength in particular in the region of 300 to 490 nm, wherein the primary radiation is partially or completely converted into radiation of a different wavelength by a previously applied conversion element, characterized in that the conversion element has a translucent or transparent substrate, which is manufactured from ceramic or glass ceramic, wherein a glass matrix is applied to the substrate, with a phosphor being embedded in said glass matrix.

### RELATED APPLICATIONS

The present application is a national stage entry according to 35 U.S.C. §371 of PCT application No.: PCT/EP2011/067381 filed on Oct. 5, 2011, which claims priority from German application No.: 102010042217.7 filed on Oct. 8, 2010.

### TECHNICAL FIELD

Various embodiments are based on an optoelectronic semiconductor component, in particular a conversion LED. Various embodiments also describe an associated production method.

### BACKGROUND

U.S. Pat. No. 5,998,925 discloses a typical white LED. In this case, the phosphor is typically suspended in silicone and then applied to the chip, usually by screen printing. The layers are approximately 30 μm thick. Silicone has poor thermal conductivity, which means that the phosphor is heated to a greater extent during operation and thus becomes less efficient. At present, the conversion element is fixed to the chip using an organic adhesive.

WO 2006/122524 describes a luminescence conversion LED which uses a phosphor which is embedded in glass.

### SUMMARY

Various embodiments provide an improved solution to the problem of heat dissipation in the conversion element in the case of an optoelectronic semiconductor component. Various embodiments provide a production method therefor.

Various embodiments solve the following problem: improved efficiency and life of the LED by virtue of greater heat dissipation of the conversion element by replacing the organic material (polymer) with glass and ceramic or glass ceramic, which have improved thermal conductivity and UV resistance.

According to various embodiments, a modified formation of a separate conversion element which is structured is used: use of a thin transparent or translucent ceramic or glass ceramic film as substrate or carrier material. The thickness of the carrier film is in the range of ≧1 μm to ≦100 μm, preferably ≧3 μm up to ≦50 μm, in particular ≧5 μm to ≦20 μm. This film can be produced, for example, by doctor blade methods and then thermally sintered. Then, a thin, compact glass layer with relatively few bubbles is laminated onto the film. The significance of a layer with few bubbles consists in its reduced scattering effect. The term having few bubbles means in particular that the proportion of bubbles in the glass layer is at most 10% by volume, preferably at most 5% by volume, particularly preferably at most 1% by volume. Owing to the temperature conditions during production of the glass matrix, this parameter can be adjusted in a targeted manner. The higher the temperature, the fewer the bubbles the glass layer will have. Sinking of the phosphor is performed at much lower temperatures in comparison to this in order to avoid any damage to the phosphor as far as possible.

The fewer the bubbles in the glass layer, the thinner the glass layer can be selected to be. This improves the homogeneity of the emission, i.e. the change in the color locus over the angle. The smaller the thickness of the glass layer, the more the undesired lateral emission is reduced.

The thickness of the glass layer is ≦200 μm, preferably ≦100 μm, in particular ≦50 μm, but at least as high as the largest phosphor particles. This layer can be applied for example by screen printing glass powder with subsequent vitrification or by drawing molten glass directly onto the film. A suitable material for the substrate is preferably Al₂O₃, YAG, AlN, AlON, SiAlON or a glass ceramic. A suitable material for the glass layer is preferably a low-melting glass, preferably free of lead or with a low lead content, with a softening temperature <500° C., preferably 350 to 480° C., as described in DE 10 2010 009 456.0, for example. Preferably, this system forms a laminate.

Then, a phosphor is applied to the glass layer of the laminate by screen printing or spraying methods, for example. The laminate coated with phosphor is then heated to such an extent (in particular the temperature is at most at the so-called hemisphere point of the glass, in particular at at least Tg of the glass, particularly preferably at at least the softening temperature of the glass) that the glass softens only slightly and the phosphor sinks into the glass layer and is surrounded thereby. The advantage of this sinking consists in that, for this purpose, only low temperatures are required and, as a result, the phosphor is not damaged. In the case of the glass from DE 10 2010 009 456.0, this is a temperature of at most 350° C. Suitable phosphors include in principle all known phosphors or mixtures of phosphors that are suitable for LED conversion, such as in particular garnets, nitridosilicates, orthosilicates, sions, sialons, calsins etc.

One alternative is the application of a powder mixture consisting of glass powder and phosphor to the sintered film, the substrate. For this purpose, however, markedly higher temperatures are required in comparison to the sinking method, in particular a temperature which at least corresponds to the melting point of the glass and preferably at most to the refining temperature of the glass, in order to produce a layer with few bubbles since the glass needs to have very low viscosity for this, so that the occluded air can escape and the phosphor particles also have a viscosity-increasing effect. Possibly additional processes, such as a vacuum during the sintering, for example, are necessary. In the case of the glass known from DE 10 2010 009 456.0, this would be at temperatures of at least 400° C.

As a further alternative, it is possible to select the substrate as a very thin film made of ceramic or glass ceramic and then to infiltrate the substrate with glass. In comparison to the two examples mentioned at the outset, the substrate in this case only needs to be sintered slightly, for which purpose the sintering temperature is lowered or the sintering time is shortened in comparison with “more compact” sintering, i.e. is only selected to be high enough for the particles of the ceramic to be fixed to one another and for many pores to remain, i.e. for a porous body to be produced. The porosity is in the region of between 30-70% by volume, preferably at least 50%. Then, a thin, at least 1 μm-thick and at most 200 μm-thick glass layer is applied directly and then heated to a temperature which corresponds at least to the melting point of the glass, preferably at most to the refining temperature of the glass, with the result that the glass becomes very fluid and, as a result of the capillary effect is drawn into the porous film, which represents the substrate. As a result, the actual substrate is formed. The glass is preferably a low-melting glass, preferably containing no or little lead, with a softening temperature of at most 500° C., as described in DE 10 2010 009 456.0, for example. The temperatures for the infiltration are in this case at least 400° C., preferably at least 500° C.

In this case, a glass excess can be applied to the film in a targeted manner in order that a thin glass layer remains on the surface of the film.

The phosphor then applied to the substrate is allowed to sink into the substrate, to be precise into the glass contained in the pores, at relatively low temperatures of at least 50° C., preferably at higher temperatures, i.e. at a temperature which at most corresponds to the hemisphere point of the glass. In the case of the glass known from DE 10 2010 009 456.0, this is a temperature of at most 350° C.

In the case of excess glass, in a first embodiment a thin glass layer into which the phosphor sinks remains on the surface of the film. In this case, the adhesion is substantially more robust than in the case of a laminate.

If, in a second embodiment, excess glass is not provided on the film surface, the phosphor sinks into the surface structure of the glass-ceramic mixture of the substrate.

The conversion element can be fixed on the chip either using an inorganic adhesive such as a low-melting glass or an inorganic sol gel or with organic adhesive such as silicone or else an organic sol gel. Likewise, it can be used as “remote phosphor”, i.e. at a distance from the chip.

In a particular configuration, the glass used for the substrate, in particular the laminate, is low-melting and is used at the same time as inorganic adhesive between the conversion element and the chip. Such a glass is described in DE 10 2010 009 456.0, for example, and makes it possible for the phosphor to sink in and for the chip and the conversion element to be adhesively bonded at temperatures ≦350° C. In this case, the glass faces the chip.

In a further configuration, the film can be coated on both sides with glass or possibly with phosphor on one or both sides. The application of the glass is performed, for example, by dipping the film in the glass melt. Then, the phosphor coating and the sinking of the phosphor into the glass takes place at low temperatures, possibly in two steps.

The substrate, in particular laminate, can also be a sandwich, i.e. the glass layer with the phosphor sunk into it is located between two films, which are made of the same or different materials and are coated on one or both sides with glass. The glass material can in this case be selected differently.

Preferably, the glass has a high refractive index (preferably n>1.8); in particular the refractive index of the glass is selected to be similar to the refractive index of the embedded phosphor component or the phosphor components and similar to the ceramic/glass ceramic.

The ceramic or glass ceramic film can face or face away from the chip. In a latter case, the ceramic also has a light-scattering effect. This is dependent inter alia, on the particle size of the particles contained in the ceramic or glass ceramic and can be influenced by the temperature treatment as well. The particle size is typically ≦60 μm, preferably ≦40 μm, particularly preferably ≦30 μm. It should be at least 1 nm, preferably at least 5 nm, more preferably at least 10 nm; for many applications a minimum value of 100 nm is sufficient.

Preferably, a bundle of conversion elements, in particular on a laminate basis, is produced as a relatively large part in one working step and only then is it cut into smaller parts, the actual conversion elements.

The thickness of the glass layer with the phosphor sunk into it should preferably be ≦200 μm, preferably ≦100 μm, in particular ≦50 μm. Preferably, the thickness of the glass layer is at least as high as the largest phosphor particles of the phosphor powder used, in particular at least twice as thick.

Suitable examples for the glass matrix are phosphate glasses and borate glasses, in particular alkaliphosphate glasses, aluminumphosphate glasses, zincphosphate glasses, phosphotetellurite glasses, bismuth borate glasses, zinc borate glasses and zinc bismuth borate glasses.

These include compositions from the following systems:

R₂O—ZnO—Al₂O₃—B₂O₃—P₂O₅ (R₂O=alkali oxide);

R₂O—TeO₂—P₂O₅ (R₂O=alkali and/or silver oxide), also in combination with ZnO and/or Nb₂O₅ such as, for example, Ag₂O—TeO₂—P₂O₅ ZnO—Nb₂O₅;

ZnO—Bi₂O₃—B₂O₃ also in combination with SiO₂ and/or alkali and/or alkaline earth metal oxide and/or Al₂O₃, such as, for example, ZnO—Bi₂O₃—B₂O₃—SiO₂ or ZnO—Bi₂O₃—B₂O₃—BaO—SrO—SiO₂;

ZnO—B₂O₃ also in combination with SiO₂ and/or alkali and/or alkaline earth metal oxide and/or Al₂O₃ such as, for example, ZnO—B₂O₃—SiO₂;

Bi₂O₃—B₂O₃ also in combination with SiO₂ and/or alkali and/or alkaline earth metal oxide and/or Al₂O₃, such as, for example, Bi₂O₃—B₂O₃—SiO₂.

Lead borate glasses are in principle suitable, but are not preferred since they are not RoHS compliant.

The carrier film may be made of a ceramic such as, for example, Al₂O₃, YAG, AlN, AlON, SiAlON etc. or a glass ceramic. The thickness of the carrier film is preferably in the region of ≦100 μm, preferably ≦50 μm, in particular ≦20 μm. However, they should be at least 1 μm, preferably 3 μm, particularly preferably at least 5 μm thick.

In a further embodiment, the crystals contained in the glass ceramic themselves can be excited to fluorescence by excitation of the primary emission of the chip and thus also contribute to the conversion. A known example is YAG:Ce.

In a particularly preferred configuration, the ceramic film contains a phosphor such as, for example, YAG:Ce, or it consists partially or completely of said phosphor. Then, a thin glass layer with few bubbles is laminated onto the ceramic film, with a separate phosphor being applied to said glass layer. This sinks into the glass owing to subsequent slight heating. The separate phosphor applied may generally be a different phosphor with an emission in a different spectral region than that of the yellow-emitting YAG:Ce. For example, the separate phosphor is a red-emitting phosphor, as a result of which warm-white light is produced with a blue-emitting chip and the yellow-emitting ceramic. The color locus of the LED can be controlled by selection of the proportion of the further phosphor.

It is also possible for an identical or similar phosphor to the phosphor already introduced into the ceramic of the substrate to be introduced additionally into the glass layer in order to compensate for a chip-related color locus fluctuation (drift), for example. It is also possible for a plurality of sorts of phosphor to be contained in the glass layer of the conversion element. These do not necessarily need to be uniformly distributed; they can also be introduced differently locally.

In addition, oxidic particles such as, for example, Al₂O₃, TiO₂, ZrO₂ as scattering means can also be added to the phosphor.

In a further configuration, two ceramics which already contain the phosphor (ceramic converters) are coated thinly with glass. The glass layer of one of the two ceramic platelets is then coated with phosphor, which sinks into this glass layer after a temperature treatment. Then, the glass surfaces of the two ceramic platelets are laid on top of the other and are adhesively bonded to one another in a further temperature step. In general, the color locus of the two ceramic platelets differs from that of the sunken phosphor.

In a particular configuration of the precursor example, only one ceramic platelet is coated thinly with glass and then adhesively bonded to the other ceramic platelet during a temperature treatment.

In addition, it is possible for the ceramic film, as substrate, to be coated on both sides thinly with glass, with the result that phosphor with the same or different emission can also be applied on both sides. A similar process is also possible with a glass ceramic as substrate. Embodiments which include combinations of the different variants as described above are likewise possible.

It is essential that the conversion element is made of a combination of glass and substrate, namely ceramic or glass ceramic, wherein a phosphor is embedded in the glass. The glass matrix can under some circumstances at the same time act as adhesive for the composite structure comprising the chip and the conversion element. The glass used should be compact, i.e. molten and with few bubbles. The substrate, whether it be ceramic or glass ceramic, can also act as light-scattering element and it is at least translucent. The substrate, whether ceramic or glass ceramic, may also itself contain phosphor or be made of phosphor.

The optoelectronic semiconductor component can be an LED or else a laser.

An optoelectronic semiconductor component includes a light source, a housing and electrical connections, wherein the light source has a chip which emits primary radiation in the UV or blue region with a peak wavelength in particular in the region of 300 to 490 nm, wherein the primary radiation is partially or completely converted into radiation of a different wavelength by a previously applied conversion element, characterized in that the conversion element has a translucent or transparent substrate, which is manufactured from ceramic or glass ceramic, wherein a glass matrix is applied to the substrate, with a phosphor being embedded in said glass matrix.

In a further embodiment, the optoelectronic semiconductor is configured such that the glass matrix is applied to the substrate as a layer.

In a still further embodiment, the substrate has pores, into which the glass matrix is introduced at least partially.

In a still further embodiment, the substrate and the glass matrix form a laminate.

In a still further embodiment, the glass matrix at the same time acts as adhesive for a composite structure comprising chip and conversion element or for a composite structure comprising two conversion elements.

In a still further embodiment, the glass matrix has few bubbles or is substantially free of bubbles.

In a still further embodiment, the substrate is itself partially or completely fluorescent.

In a still further embodiment, a glass matrix is applied to both sides of the substrate.

In a still further emcodiment, the conversion element is fastened by means of an adhesive on the chip or is attached spaced apart from the chip.

In a further embodiment, a method for producing a conversion element for an optoelectronic semiconductor component discloses, in a first step, a substrate is provided which is produced from ceramic or glass ceramic, then in a second step, glass is applied to the substrate, in particular in the form of glass powder or molten glass, wherein either phosphor is applied together with the glass, or phosphor is introduced subsequently into the glass.

In a still further embodiment, in the second step, a glass layer is laminated, in particular either by screen printing glass powder with subsequent vitrification or by drawing molten glass directly onto the substrate.

In a still further embodiment, the phosphor is then applied by screen printing or by a spraying method to the glass layer and then the conversion element is heated to such an extent that the glass is heated slightly, with the result that the phosphor sinks into the glass and is surrounded thereby.

In a still further embodiment, in the second step, a glass layer is laminated, which glass layer has already been provided with phosphor, in particular by screen printing of glass powder which has previously been mixed with phosphor powder, with subsequent vitrification.

In a still further embodiment, in the second step, a glass matrix is produced by infiltration, wherein the substrate has previously been sintered so slightly that it contains large pores, which are large enough for taking up glass, wherein the glass is made sufficiently fluid for it to be drawn into the pores of the substrate by the capillary effect.

### BRIEF DESCRIPTION OF THE DRAWINGS

In the drawings, like reference characters generally refer to the same parts throughout the different views. The drawings are not necessarily to scale, emphasis instead generally being replaced upon illustrating the principles of the invention. In the following description, various embodiments of the invention are described with reference to the following drawings, in which:

FIG. 1 shows a conversion LED in accordance with the prior art;

FIG. 2 shows an LED with a novel converter element;

FIGS. 3-7 each show a further exemplary embodiment of an LED with a novel converter element;

FIG. 8 shows a substrate with pores and a glass matrix contained therein which contains phosphor particles.

### DETAILED DESCRIPTION

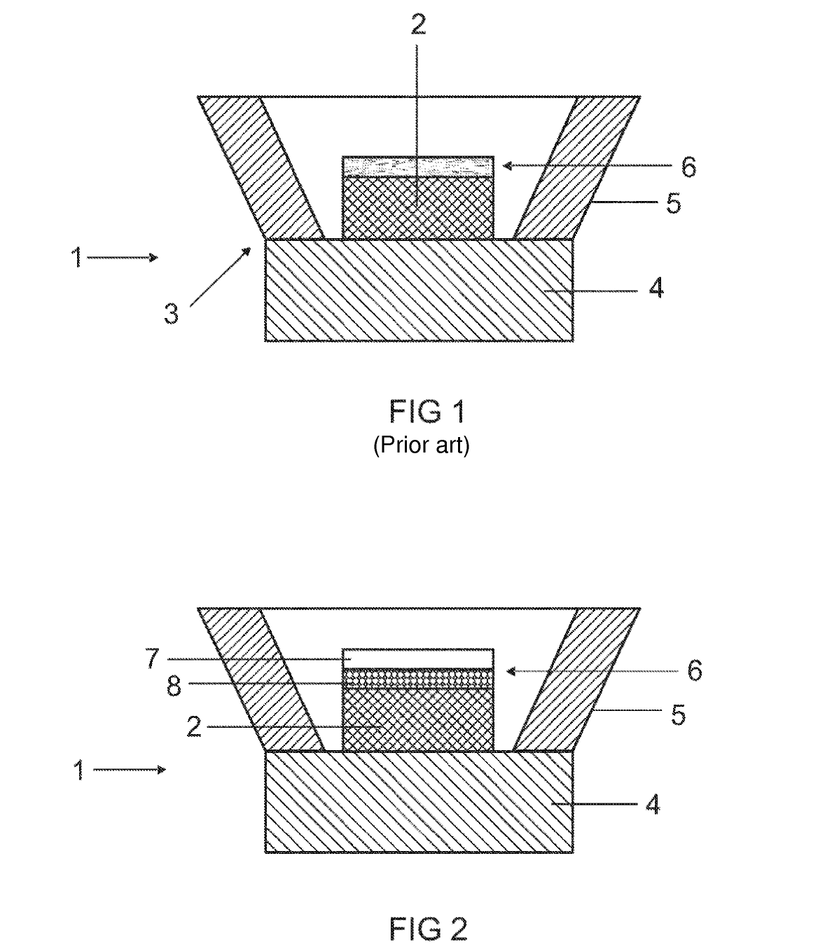

FIG. 1 shows, as semiconductor component, a conversion LED 1, which uses a chip 2 of the type InGaN as primary radiation source. It has a housing 3 with a board 4, on which the chip is positioned, and a reflector 5. A conversion element 6 which partially converts the blue radiation into longer-wave radiation by means of a phosphor, for example YAG:Ce, is upstream of the chip. The conversion element 6 is in the form of a platelet in accordance with the prior art and has a silicone bed, in which phosphor powder is dispersed. The electrical connections are not illustrated, but they correspond to conventional technology.

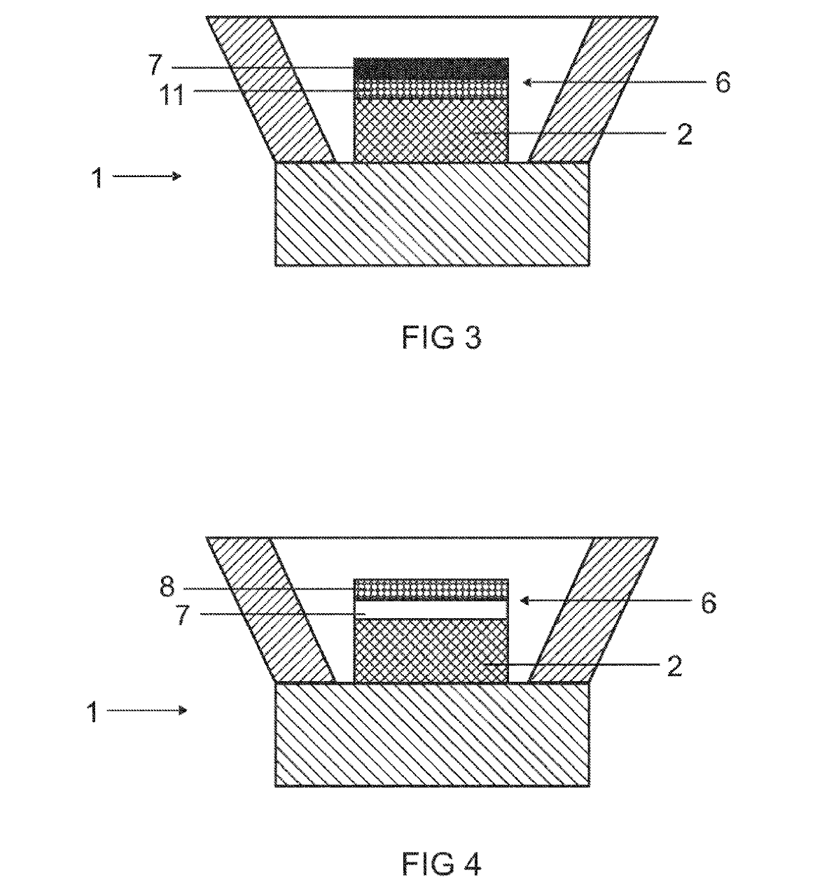

FIG. 2 shows a first embodiment according to the invention. In this case, a substrate 7 made of Al₂O₃ is used as conversion element 6, which substrate is translucent and is shaped in platelet-like fashion as a film. A thin glass layer 8 is applied to the substrate 7, in the sense of a matrix. Phosphor particles are distributed in this matrix, said phosphor particles having been sunk into the glass matrix and being completely covered thereby. Glass layer 8 and substrate 7 form a laminate, wherein that side of the substrate on which the glass matrix has been applied faces the chip 2, or else faces away from said chip 2. The conversion element is applied to the chip by means of known adhesives (not illustrated).

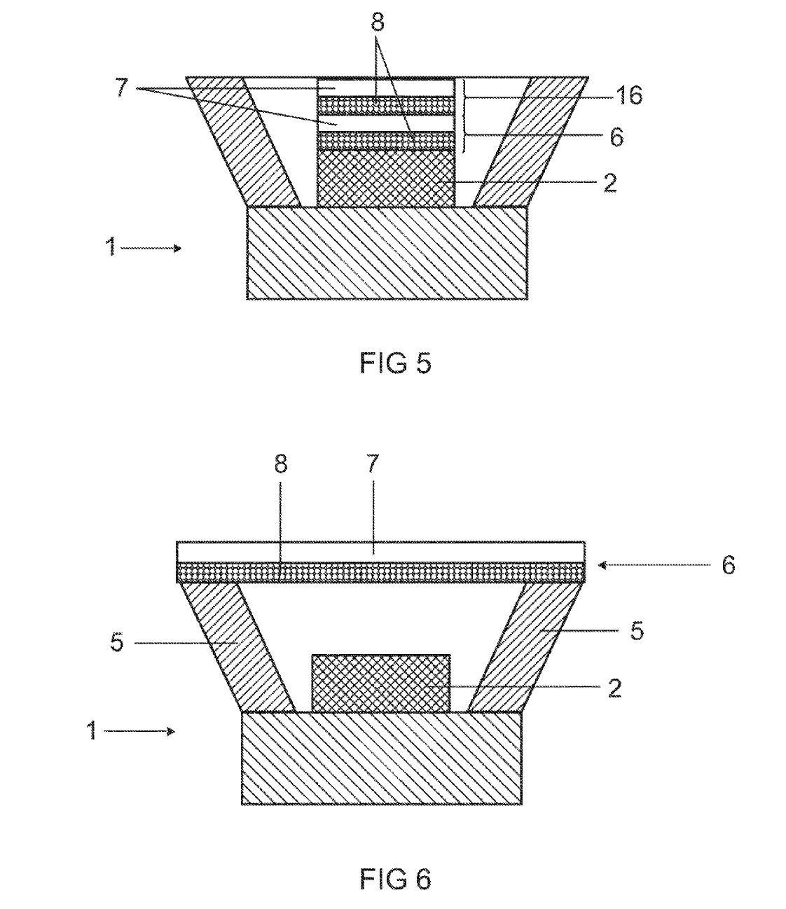

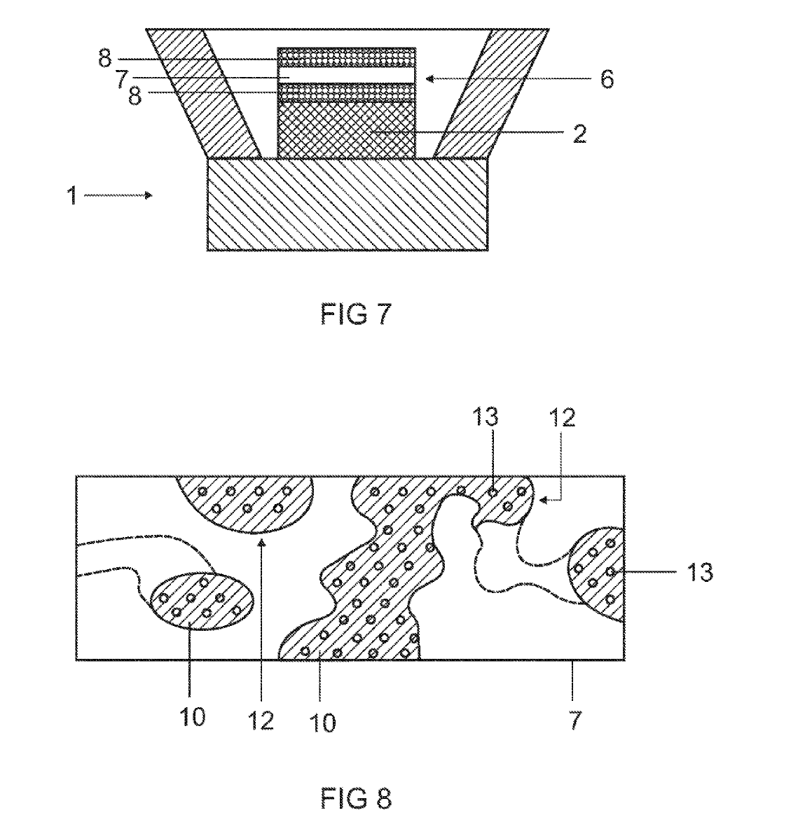

FIG. 3 shows an embodiment of an LED 1, in which the film consisting of ceramic or glass ceramic, which acts as substrate 7, has been partially sintered only briefly at a low temperature. Therefore, it has many open pores. The glass matrix fills these pores. By virtue of the use of an excess of glass, a thin layer 11 of glass also remains on the surface of the substrate. The phosphor is dispersed in the glass matrix both in the region of the thin layer 11 and in the region of the pores. A similar configuration is shown in FIG. 8 in detail without the layer 11. Said figure shows the substrate 7 with the pores 12 open. The glass matrix 10 has sunk into the pores. Phosphor particles 13 are dispersed in the glass matrix.

FIG. 4 shows, schematically, an exemplary embodiment of an LED 1, in which the substrate 7 is connected to the chip 2 of the type InGaN, which emits blue (peak at approximately 440 to 450 nm), via a conventional adhesive layer (not additionally illustrated). The glass matrix 8 with the phosphor which has sunk therein is fixed on that side of the substrate 7 which faces away from the chip. The conventional adhesive layer is usually silicone. It is used when relatively temperature-sensitive chips are used.

In the case of less temperature-sensitive chips, an adhesive layer consisting of glass with a high refractive index is more advantageous. This is because the heat dissipation is better and also the light output is greater. This increases efficiency.

For this reason, an independent technical solution is to use the proposed glasses with high refractive indices alone as adhesive (in particular in the direction towards the chip or the housing), i.e. without embedding a phosphor. In this case, the phosphor on its own is introduced into the ceramic substrate or a plurality of phosphor-containing ceramic substrates can be joined with one another via such an adhesive.

FIG. 5 shows, schematically, an embodiment of an LED 1, in which a double structure of the conversion element 6, 16 is used. Starting from the blue-emitting chip, there follows, on a first layer 8 with glass matrix and first phosphor, preferably a red-emitting phosphor such as a nitridosilicate M₂Si₅N₈:Eu, a first substrate 7, which is in turn connected to a second glass matrix 8, which is in turn connected to a second substrate 7. In this case, the glass matrix 8 in each case acts as adhesive itself.

Suitable phosphors are in particular YAG:Ce or another garnet, orthosilicate or sion, nitridosilicate, sialon, calsin, etc.

FIG. 6 shows an embodiment of an LED 1 with an upstream conversion element 6 spaced apart from the chip 2. In this case, the side wall 5 of the housing, which side wall acts as reflector, by virtue of, for example, the inner wall being coated suitably, bears the conversion element 6 at its end. Again the glass matrix 8 also acts as adhesive towards the side wall, and the substrate 7 is facing away from the chip. The conversion element 6 closes the opening of the reflector.

FIG. 7 shows an embodiment of an LED 1, in which a conversion element 6 has a sandwich-like structure. It uses a UV-emitting chip 2 with a peak wavelength of approximately 380 nm. A first glass matrix 8 adhesively bonds directly on the chip 2, with a first phosphor dispersed in said glass matrix, for example a red, UV-excitable phosphor such as the calsin CaAlSiN₃:Eu. A substrate 7 made of a mixture of YAG and YAG:Ce which emits yellow is positioned in front of the first glass matrix. An additional blue-emitting phosphor such as BAM:Eu is dispersed in a second glass matrix 8, which is applied externally in front of the substrate 7.

Embodiments of a converter for the conversion of the UV component into blue light are, for example, high-efficiency phosphors of the type (Ba_{0.4}Eu_{0.6}) MgAl₁₀O₁₇, (Sr_{0.96}Eu_{0.04})₁₀(PO₄)₆Cl₂. An embodiment of a converter for the conversion of the UV component into yellow light is, for example,

(Sr_{1-x-y}CeₓLi_{y})₂Si₅N₈. In particular, in this case x and y are each in the range of 0.1 to 0.01. Particularly suitable is a phosphor (Sr_{1-x-y}CeₓLi_{y})₂Si₅N₈ where x=y. Embodiments of a converter for the conversion of the UV component into red light are, for example, nitridosilicates, calsins and sions of the type MSi2O2N2:Eu, which are well known per se.

1. An optoelectronic semiconductor component comprising a light source, a housing and electrical connections, wherein the light source has a chip which emits primary radiation in the UV or blue region with a peak wavelength in particular in the region of 300 to 490 nm, wherein the primary radiation is partially or completely converted into radiation of a different wavelength by a previously applied conversion element, wherein the conversion element has a translucent or transparent substrate, which is manufactured from ceramic or glass ceramic, wherein a glass matrix is applied to the substrate, with a phosphor being embedded in said glass matrix.

2. The optoelectronic semiconductor component as claimed in claim 1, wherein the glass matrix is applied to the substrate as a layer.

3. The optoelectronic semiconductor component as claimed in claim 1, wherein that the substrate has pores, into which the glass matrix is introduced at least partially.

4. The optoelectronic semiconductor component as claimed in claim 1, wherein the substrate and the glass matrix form a laminate.

5. The optoelectronic semiconductor component as claimed in claim 1, wherein the glass matrix at the same time acts as adhesive for a composite structure comprising chip and conversion element or for a composite structure comprising two conversion elements.

6. The optoelectronic semiconductor component as claimed in claim 1, wherein the glass matrix has few bubbles or is substantially free of bubbles.

7. The optoelectronic semiconductor component as claimed in claim 1, wherein the substrate is itself partially or completely fluorescent.

8. The optoelectronic semiconductor component as claimed in claim 1, wherein a glass matrix is applied to both sides of the substrate.

9. The optoelectronic semiconductor component as claimed in claim I, wherein the conversion element is fastened by means of an adhesive on the chip or is attached spaced apart from the chip.

10. A method for producing a conversion element for an optoelectronic semiconductor component, the optoelectronic semiconductor component comprising a light source, a housing and electrical connections wherein the light source has a chip which emits primary radiation in the UV or blue region with a peak wavelength in particular in the region of 300 to 490 nm, wherein the primary radiation is partially or completely converted into radiation of a different wavelength by a previously applied conversion element, wherein the conversion element has a translucent or transparent substrate, which is manufactured from ceramic or glass ceramic, wherein a glass matrix is applied to the substrate, with a phosphor being embedded in said glass matrix, the method comprises, in a first step, a substrate is provided which is produced from ceramic or glass ceramic, then in a second step, glass is applied to the substrate, in particular in the form of glass powder or molten glass, wherein either phosphor is applied together with the glass, or phosphor is introduced subsequently into the glass.

11. The method as claimed in claim 10, wherein in the second step, a glass layer is laminated, in particular either by screen printing glass powder with subsequent vitrification or by drawing molten glass directly onto the substrate.

12. The method as claimed in claim 11, wherein the phosphor is then applied by screen printing or by a spraying method to the glass layer and then the conversion element is heated to such an extent that the glass is heated slightly, with the result that the phosphor sinks into the glass and is surrounded thereby.

13. The method as claimed in claim 10, wherein in the second step, a glass layer is laminated, which glass layer has already been provided with phosphor, in particular by screen printing of glass powder which has previously been mixed with phosphor powder, with subsequent vitrification.

14. The method as claimed in claim 10, wherein in the second step, a glass matrix is produced by infiltration, wherein the substrate has previously been sintered in such a way that it contains large pores, wherein the glass is made sufficiently fluid for it to be drawn into the pores of the substrate by the capillary effect.
